(19) United States
(12) Patent Application Publication
(10) Pub. No.: US 2009/0315086 A1
(43) Pub. Date: Dec. 24, 2009

(54) IMAGE SENSOR AND CMOS IMAGE SENSOR

(75) Inventors: Mamoru Arimoto, Ogaki-shi (JP); Kaori Misawa, Kaizu-shi (JP); Hayato Nakashima, Anpachi-gun (JP); Ryu Shimizu, Mizuho-shi (JP)

Correspondence Address: DITTHAVONG MORI & STEINER, P.C., 918 Prince St., Alexandria, VA, 22314, US

(73) Assignee: Sanyo Electric Co., Ltd., Moriguchi-shi (JP)

(21) Appl. No.: 12/486,495

(22) Filed: Jun. 17, 2009

(30) Foreign Application Priority Data
Jun. 24, 2008 (JP) 2008-164178

(51) Int. Cl. H01L 31/112; H01L 31/101

(52) U.S. Cl. 257/292; 257/448; 257/E31.079; 257/E31.054

(57) ABSTRACT

An image sensor includes a first electrode for applying a voltage to a charge storage portion, a second electrode for applying a voltage to a charge increasing portion, a third electrode provided between the first electrode and the second electrode and an impurity region of a first conductive type for forming a path through which the signal charges are transferred, wherein an impurity concentration of a region of the impurity region corresponding to a portion located under the second electrode is higher than an impurity concentration of a region of the impurity region corresponding to a portion located under the third electrode.

### CROSS-REFERENCE TO RELATED APPLICATIONS

The priority application number JP2008-164178, Image Sensor, Jun. 24, 2008, Mamoru Arimoto, Kaori Misawa, Hayato Nakashima, Ryu Shimizu, upon which this patent application is based is hereby incorporated by reference.

### BACKGROUND OF THE INVENTION

1. Field of the Invention

The present invention relates to an image sensor and a CMOS image sensor, and more particularly, it relates to an image sensor and a CMOS image sensor each comprising a charge increasing portion for increasing signal charges.

2. Description of the Background Art

An image sensor comprising a charge increasing portion (electron increasing portion) for increasing signal charges is known in general.

An image sensor comprising an electron storage portion for storing electrons (signal charges), a storage gate electrode for storing the electrons in the electron storage portion, an electron increasing portion for impact-ionizing and increasing (multiplying) the electrons stored in the electron storage portion, a multiplier gate electrode for forming an electric field increasing the electrons by impact-ionization on the electron increasing portion, a transfer gate electrode provided between the storage gate electrode and the multiplier gate electrode, and an impurity region for forming a path through which electrons are transferred, provided under the multiplier gate electrode, the transfer gate electrode and the storage gate electrode is disclosed. In this image sensor, electrons are repeatedly transferred between the electron storage portion and the electron increasing portion, thereby increasing the electrons.

### SUMMARY OF THE INVENTION

An image sensor according to a first aspect of the present invention comprises a charge storage portion for storing signal charges, a first electrode for applying a voltage to the charge storage portion, a charge increasing portion for increasing the signal charges stored in the charge storage portion by impact-ionization, a second electrode for applying a voltage to the charge increasing portion, a third electrode for transferring the signal charges, provided between the first electrode and the second electrode and an impurity region of a first conductive type for forming a path through which the signal charges are transferred, provided on portions located under at least the first electrode, the second electrode and the third electrode, wherein an impurity concentration of a region of the impurity region corresponding to the portion located under the second electrode is higher than an impurity concentration of a region of the impurity region corresponding to the portion located under the third electrode.

A CMOS image sensor according to a second aspect of the present invention comprises a charge storage portion for storing signal charges, a first electrode for applying a voltage to the charge storage portion, a charge increasing portion for increasing the signal charges stored in the charge storage portion by impact-ionization, a second electrode for applying a voltage to the charge increasing portion, a third electrode for transferring the signal charges, provided between the first electrode and the second electrode and an impurity region of a first conductive type for forming a path through which the signal charges are transferred, provided on portions located under at least the first electrode, the second electrode and the third electrode, wherein the charge storage portion, the charge increasing portion, the first electrode, the second electrode and the third electrode are provided in one pixel, and an impurity concentration of a region of the impurity region corresponding to the portion located under the second electrode is higher than an impurity concentration of a region of the impurity region corresponding to the portion located under the third electrode.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing an overall structure of a CMOS image sensor according to a first embodiment of the present invention;

FIGS. 2 and 3 are sectional views showing the structure of the CMOS image sensor according to the first embodiment of the present invention;

FIG. 4 is a plan view showing a pixel of the CMOS image sensor according to the first embodiment of the present invention;

FIG. 5 is a circuit diagram showing a circuit structure of the CMOS image sensor according to the first embodiment of the present invention;

FIG. 6 is a signal waveform diagram for illustrating electron transferring and multiplying operations of the CMOS image sensor according to the first embodiment of the present invention;

FIG. 7 is a potential diagram for illustrating the electron transferring and multiplying operations of the CMOS image sensor according to the first embodiment of the present invention;

FIG. 8 is a signal waveform diagram for illustrating electron transferring and multiplying operations of the CMOS image sensor according to the first embodiment of the present invention;

FIG. 9 is a potential diagram for illustrating the electron transferring and multiplying operations of the CMOS image sensor according to the first embodiment of the present invention;

FIG. 10 is a diagram showing a profile of an impurity implanted into a buried layer according to the first embodiment of the present invention;

FIG. 11 is a diagram showing a potential in the vicinity of an interface between a gate insulating film and a buried layer according to the first embodiment of the present invention;

FIG. 12 is a potential diagram in a CMOS image sensor according to a second embodiment of the present invention; and

FIGS. 13 and 14 are potential diagrams for illustrating electron transferring and multiplying operations of the CMOS image sensor according to the second embodiment of the present invention.

### DESCRIPTION OF THE PREFERRED EMBODIMENTS

Embodiments of the present invention will be hereinafter described with reference to the drawings.

### First Embodiment

The first embodiment of the present invention is applied to an active CMOS image sensor employed as an exemplary image sensor.

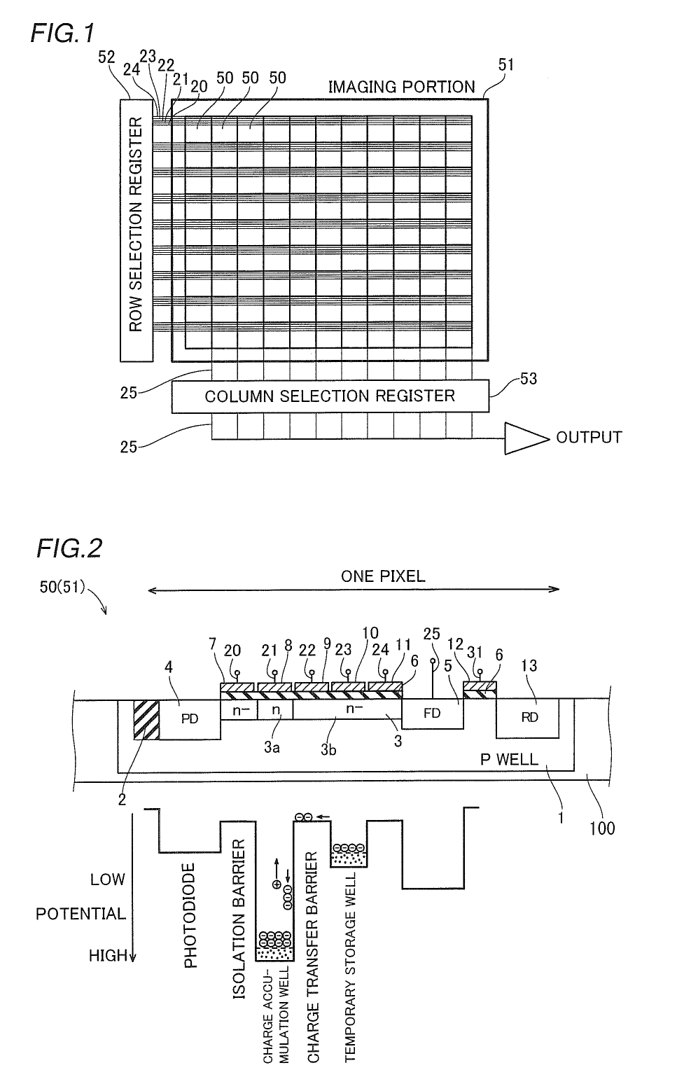

The CMOS image sensor according to the first embodiment comprises an imaging portion 51 including a plurality of pixels 50 arranged in the form of a matrix, a row selection register 52 and a column selection register 53, as shown in FIG. 1.

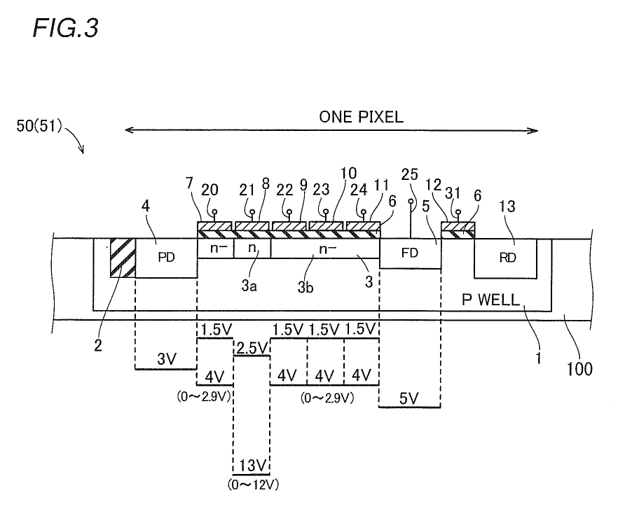

As to the sectional structure of the pixels 50 of the CMOS image sensor, element isolation regions 2 for isolating the pixels 50 from each other are formed on a surface of a p-type well region 1 formed on a surface of an n-type silicon substrate 100, as shown in FIGS. 2 and 3. The n-type silicon substrate 100 is an example of the “semiconductor substrate” in the present invention. On a surface of the p-type silicon region 1 provided with each of pixels 50 enclosed with the corresponding element isolation regions 2, a photodiode (PD) portion 4 and a floating diffusion (FD) region 5 consisting of an n-type impurity region are formed at a prescribed interval, to hold a buried layer 3 consisting of an n⁻-type and n-type impurity regions therebetween. The buried layer 3 is an example of the “impurity region” in the present invention. The photodiode portion 4 is an example of the “photoelectric conversion portion” in the present invention, and the FD region 5 is an example of the “voltage conversion portion” in the present invention.

A peak concentration of the impurity in the region (electron multiplying portion 3a) of the buried layer 3 located under a multiplier gate electrode 8, described later, is higher than a peak concentration of the impurity in each of regions of the buried layer 3 located under remaining electrodes other than the multiplier gate electrode 8. More specifically, the peak concentration of the impurity in each of the portions of the buried layer 3 located under the remaining electrodes other than the multiplier gate electrode 8 is about 8.5×10¹⁶ cm⁻³, while the peak concentration of the impurity in the portion (electron multiplying portion 3a) of the buried layer 3 located under the multiplier gate electrode 8 is about 2.5×10¹⁷ cm⁻³. For example, arsenic (As) is implanted as the impurity. Thus, a potential of the portion of the buried layer 3 located under the multiplier gate electrode 8 is rendered higher than that of the portion of the buried layer 3 located under each of the remaining electrodes other than the multiplier gate electrode 8, when the same level signals are supplied (the same voltages are applied) to the electrodes respectively.

The PD portion 4 has a function of generating electrons in response to the quantity of incident light and storing the generated electrons, and is formed to be adjacent to the corresponding element isolation region 2 as well as to the buried layer 3. The FD region 5 has a function of holding signal charges formed by transferred electrons and converting the signal charges to a voltage. The FD region 5 is formed to be adjacent to the corresponding buried layer 3.

A gate insulating film 6 made of SiO₂ is formed on an upper surface of the buried layer 3. On the gate insulating film 6, the transfer gate electrode 7, the multiplier gate electrode 8, the transfer gate electrode 9, the storage gate electrode 10 and the read gate electrode 11 are formed in this order from a side of the PD portion 4 toward a side of the FD region 5. A reset gate electrode 12 is formed through the gate insulating film 6 to be adjacent to the FD region 5, and a reset drain region (RD region) 13 is formed to be opposed to the FD region 5 with the reset gate electrode 12 therebetween. The electron multiplying portion 3a is provided on the portion of the buried layer 3 located under the multiplier gate electrode 8, and an electron storage portion 3b is provided on the portion of the buried layer 3 located under the storage gate electrode 10. The transfer gate electrode 7, the multiplier gate electrode 8, the transfer gate electrode 9, the storage gate electrode 10 and the read gate electrode 11 are examples of the “fourth electrode”, the “second electrode”, the “third electrode”, the “first electrode” and the “fifth electrode” in the present invention. The electron multiplying portion 3a is an example of the “charge increasing portion” in the present invention. The electron storage portion 3b is an example of the “charge storage portion” in the present invention.

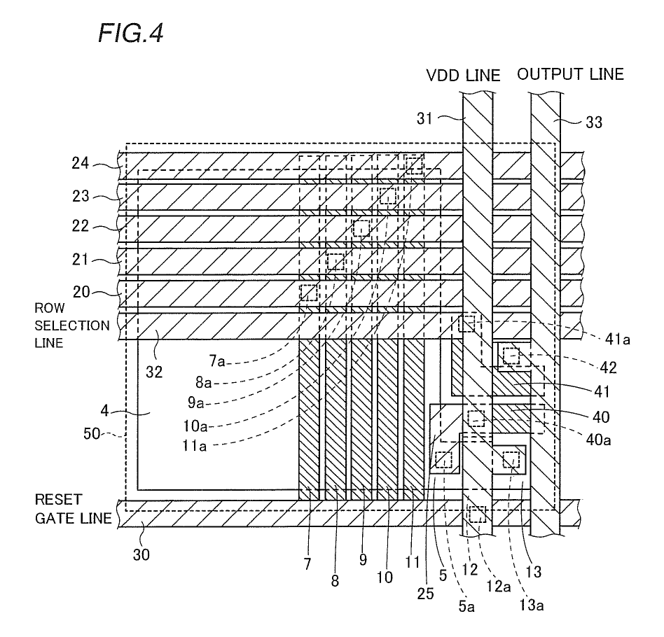

As shown in FIGS. 3 and 4, wiring layers 20, 21, 22, 23 and 24 supplying clock signals φ1, φ2, φ3, φ4 and φ5 for voltage control are electrically connected to the transfer gate electrode 7, the multiplier gate electrode 8, the transfer gate electrode 9, the storage gate electrode 10 and the read gate electrode 11 through contact portions 7a, 8a, 9a, 10a and 11a respectively. The wiring layers 20, 21, 22, 23 and 24 are formed every row, and electrically connected to the transfer gate electrode 7, the multiplier gate electrode 8, the transfer gate electrode 9, the storage gate electrode 10 and the read gate electrode 11 of the plurality of pixels 50 forming each row respectively. A signal line 25 for extracting a signal through a contact portion 5a is electrically connected to the FD region 5.

As shown in FIG. 3, when ON-state (high-level) clock signals φ1, φ3, φ4 and φ5 are supplied to the transfer gate electrodes 7 and 9, the storage gate electrode 10 and the read gate electrode 11 through the wiring layers 20, 22, 23 and 24 respectively, voltages of about 2.9 V are applied to the transfer gate electrodes 7 and 9, the storage gate electrode 10 and the read gate electrode 11.

The portions of the buried layer 3 located under the transfer gate electrodes 7 and 9, the storage gate electrode 10 and the read gate electrode 11 respectively are controlled to potentials of about 4 V when the voltages of about 2.9 V are applied (high-level signals are supplied) to the transfer gate electrodes 7 and 9, the storage gate electrode 10 and the read gate electrode 11 respectively.

When the ON-state (high-level) clock signal φ2 is supplied to the multiplier gate electrode 8 from the wiring layer 21, a voltage of about 12 V is applied to the multiplier gate electrode 8. Thus, when the ON-state (high-level) clock signal φ2 is supplied to the multiplier gate electrode 8, the portion of the buried layer 3 located under the multiplier gate electrode 8 is controlled to a high potential of about 13 V.

When OFF-state (low-level) clock signals φ1, φ2, φ3, φ4 and φ5 are supplied to the transfer gate electrode 7, the multiplier gate electrode 8, the transfer gate electrode 9, the storage gate electrode 10 and the read gate electrode 11 respectively, voltages of about 0 V are applied to the transfer gate electrode 7, the multiplier gate electrode 8, the transfer gate electrode 9, the storage gate electrode 10 and the read gate electrode 11. At this time, the portions of the buried layer 3 located under the transfer gate electrodes 7 and 9, the storage gate electrode 10 and the read gate electrode 11 respectively are controlled to potentials of about 1.5 V and the potential of the portion (electron multiplying portion 3a), formed to have a high concentration, of the buried layer 3 located under the multiplier gate electrode 8 is controlled to a potential of about 2.5 V.

The FD region 5 is controlled to a potential of about 5 V. The reset drain region 13 is controlled to a potential of about 5 V, and has a function as an ejecting portion of electrons held in the FD region 5.

The transfer gate electrode 7 has a function of transferring electrons generated by the PD portion 4 to the electron multiplying portion 3a located on the portion of the buried layer 3 located under the multiplier gate electrode 8 through the portion of the buried layer 3 located under the transfer gate electrode 7 by supplying the ON-state (high-level) signal to the transfer gate electrode 7. The portion of the buried layer 3 located under the transfer gate electrode 7 has a function as an isolation barrier dividing the PD portion 4 and portion of the buried layer 3 located under the multiplier gate electrode 8 (electron multiplying portion 3a) from each other when the OFF-state (low-level) signal is supplied to the transfer gate electrode 7.

The multiplier gate electrode 8 is supplied with the ON-state signal, so that a high electric field is applied to the electron multiplying portion 3a located on the portion of the buried layer 3 located under the multiplier gate electrode 8. Then the speed of electrons transferred from the PD portion 4 through the portion of the buried layer 3 located under the transfer gate electrode 7 is increased by a high electric field generated in the electron multiplying portion 3a and the electrons are multiplied by impact-ionization with atoms in the buried layer 3.

The transfer gate electrode 9 has a function of transferring electrons between the portion (electron multiplying portion 3a) of the buried layer 3 located under the multiplier gate electrode 8 and the electron storage portion 3b provided on the portion of the buried layer 3 located under the storage gate electrode 10 by supplying the ON-state signal to the transfer gate electrode 9. When the OFF-state signal is supplied to the transfer gate electrode 9, the transfer gate electrode 9 functions as a charge transfer barrier for suppressing transfer of electrons between the electron multiplying portion 3a located under the multiplier gate electrode 8 and the electron storage portion 3b located under the storage gate electrode 10.

When the ON-state signal is supplied to the read gate electrode 11, the read gate electrode 11 has a function of transferring electrons stored in the portion of the buried layer 3 (electron storage portion 3b) located under the storage gate electrode 10 to the FD region 5. When the OFF-state signal is supplied to the read gate electrode 11, the read gate electrode 11 has a function of dividing the portion (electron storage portion 3b) of the buried layer 3 located under the storage gate electrode 10 and the FD region 5.

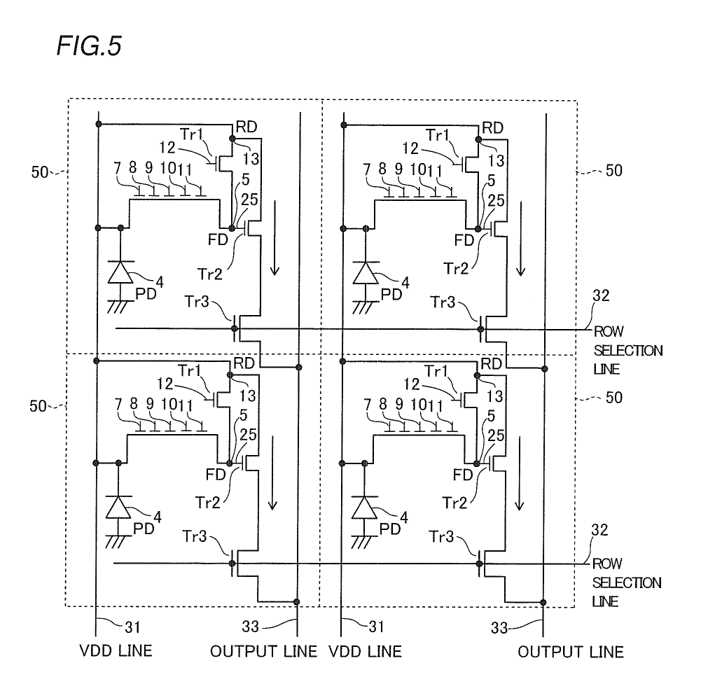

As shown in FIGS. 4 and 5, each pixel 50 includes a reset transistor Tr1, an amplification transistor Tr2 and a pixel selection transistor Tr3. A reset gate line 30 is connected to the reset gate electrode 12 of the reset transistor Tr1 through the contact portion 12a, to supply a reset signal. A drain (reset drain 13) of the reset transistor Tr1 is connected to a power supply potential (VDD) line 31 through another contact portion 13a. The FD region 5 constituting sources of the reset transistor Tr1 and the read gate electrode 11 and a gate 40 of the amplification transistor Tr2 are connected with each other through the contact portions 5a and 40a by the signal line 25. A drain of the pixel selection transistor Tr3 is connected to a source of the amplification transistor Tr2. A row selection line 32 and an output line 33 are connected to a gate 41 and a source of the pixel selection transistor Tr3 through the contact portions 41a and 42 respectively.

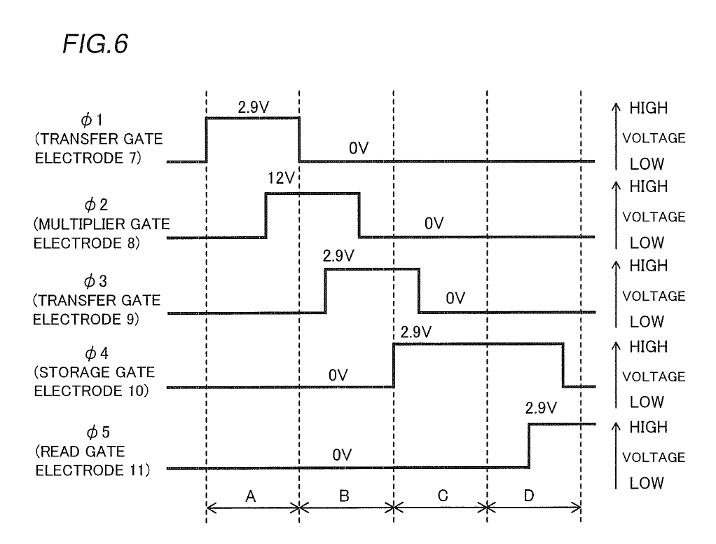

An electron transferring and multiplying operations of the CMOS image sensor according to the first embodiment of the present invention will be described with reference to FIGS. 6 to 9.

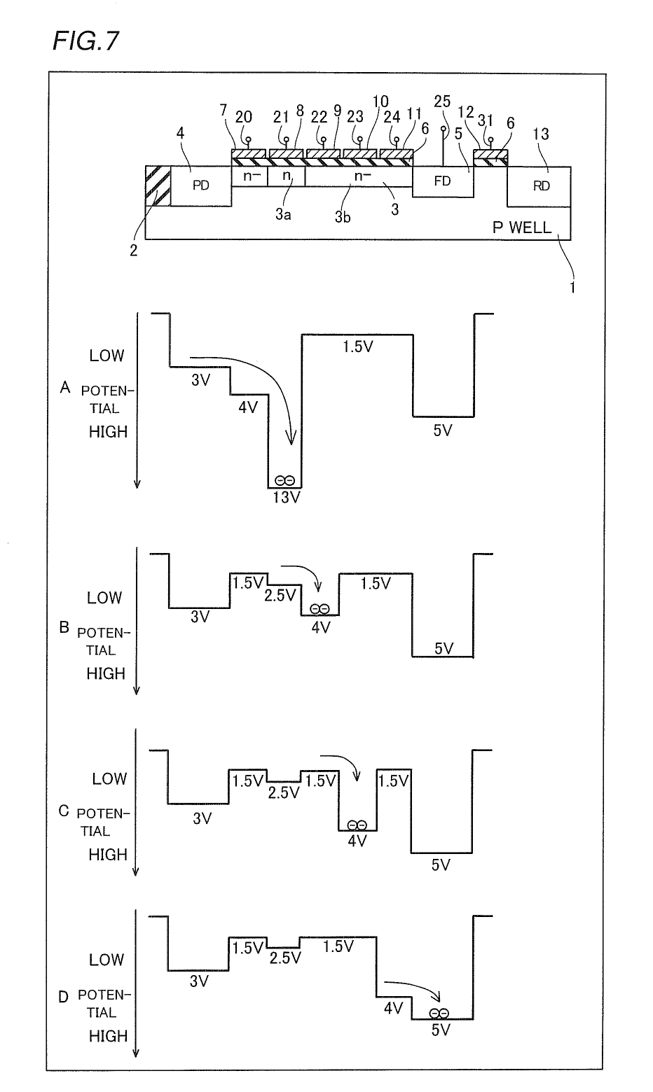

When light is incident upon the PD portion 4, electrons are generated in the PD portion 4 by photoelectric conversion. In a period A shown in FIGS. 6 and 7, a voltage of about 12 V is applied to the multiplier gate electrode 8 after a voltage of about 2.9 is applied to the transfer gate electrode 7. Thus, the potential of the portion of the buried layer 3 located under the multiplier gate electrode 8 is controlled to a high potential of about 13 V in the state where the potential of the portion of the buried layer 3 located under the transfer gate electrode 7 is controlled to a potential of about 4. At this time, electrons generated by the PD portion 4 (about 3 V) are transferred to the portion (electron multiplying portion 3a) of the buried layer 3 located under the multiplier gate electrode 8 (higher potential of about 13 V) through the portion of the buried layer 3 located under the transfer gate electrode 7 (about 4V), and the electrons are multiplied on the electron multiplying portion 3a by impact ionization. Thereafter a voltage of about 0 V is applied to the transfer gate electrode 7.

In a period B, a voltage of about 2.9 V is applied to the transfer gate electrode 9 and a voltage of about 0 V is thereafter applied to the multiplier gate electrode 8. Thus, electrons are transferred from the electron multiplying portion 3a (about 2.5 V) under the multiplier gate electrode 8 to the portion of the buried layer 3 located under the transfer gate electrode 9 (higher potential of about 4V).

In a period C, a voltage of about 2.9 is applied to the storage gate electrode 10 and a voltage of about 0 V is thereafter applied to the transfer gate electrode 9. Thus, the electrons are transferred from the portion of the buried layer 3 located under the transfer gate electrode 9 to the portion (electron storage portion 3b) of the buried layer 3 located under the storage gate electrode 10 (higher potential of about 4 V).

In a period D, a voltage of about 2.9 V is applied to the read gate electrode 11, to control the potential of the portion of the buried layer 3 located under the read gate electrode 11 to a potential of about 4 V. Then a voltage of about 0 V is applied to the storage gate electrode 10. Thus, the electrons are transferred to the FD region 5 through the portion of the buried layer 3 located under the read gate electrode 11 (about 4 V). Thus, the electron transferring operation is completed.

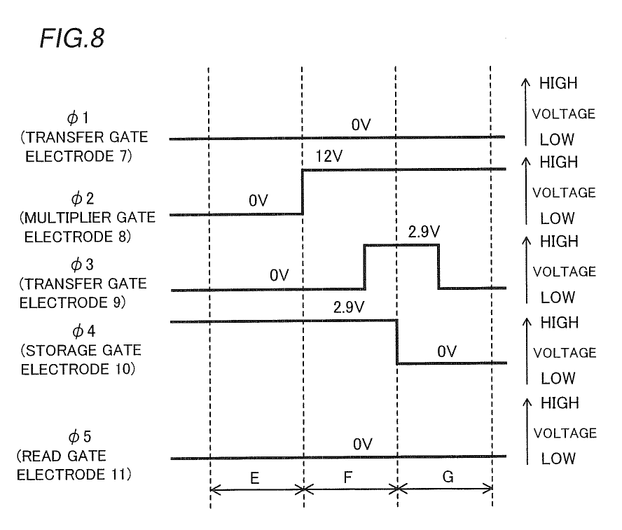

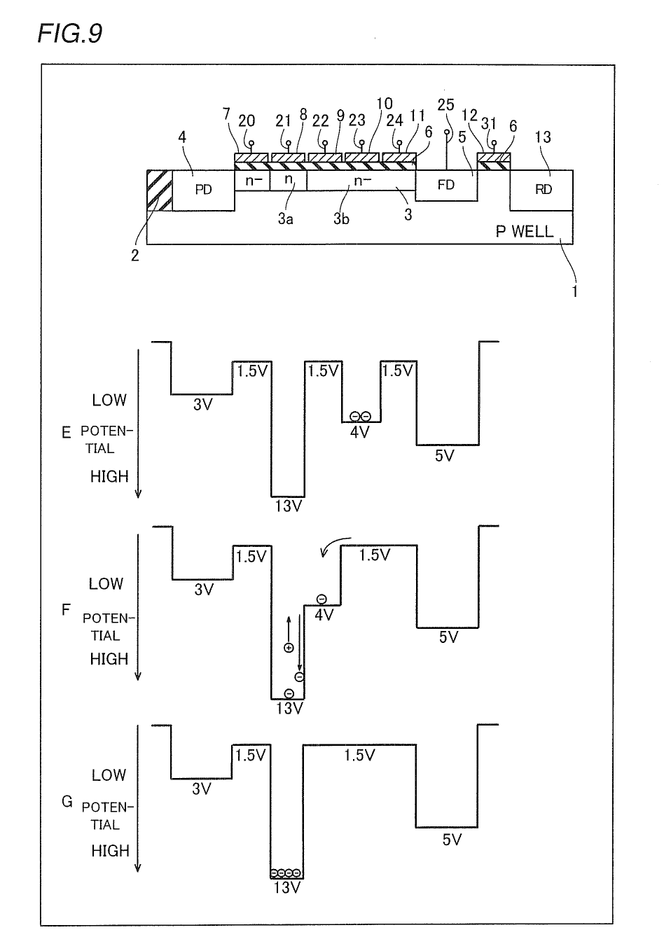

In the electron multiplying operation, a voltage of about 12 V is applied to the multiplier gate electrode 8 in a period E shown in FIGS. 8 and 9 and a voltage of about 2.9 V is applied to the transfer gate electrode 9 in a period F, in the state where the portion of the buried layer 3 located under the storage gate electrode 10 (electron storage portion 3b) stores electrons by performing the operations of the periods A to C in FIGS. 6 and 7. Thus, the portion (electron multiplying portion 3a) of the buried layer 3 located under the multiplier gate electrode 8 is controlled to a potential of about 13 V and the portion of the buried layer 3 located under the transfer gate electrode 9 is thereafter controlled to a potential of about 4 V. Then a voltage of about 0 V is applied to the storage gate electrode 10, to transfer the electrons stored in the electron storage portion 3b to the portion (electron multiplying portion 3a), having a higher potential, of the buried layer 3 located under the multiplier gate electrode 8 through the portion of the buried layer 3 located under the transfer gate electrode 9 (about 4 V).

The electrons are transferred to the electron multiplying portion 3a to be multiplied in the aforementioned manner. A voltage of about 0 V is applied to the transfer gate electrode 9 in a period G, thereby completing the electron multiplying operation. The aforementioned operation in the periods A to C and the periods E to G (electron transferring operation between the electron multiplying portion 3a and the electron storage portion 3b) is controlled to be performed a plurality of times (about 400 times, for example), thereby multiplying the electrons transferred from the PD portion 4 to about 2000 times. Signal charges by thus multiplied and stored electrons are read as a voltage signal through the FD region 5 and the signal line 25.

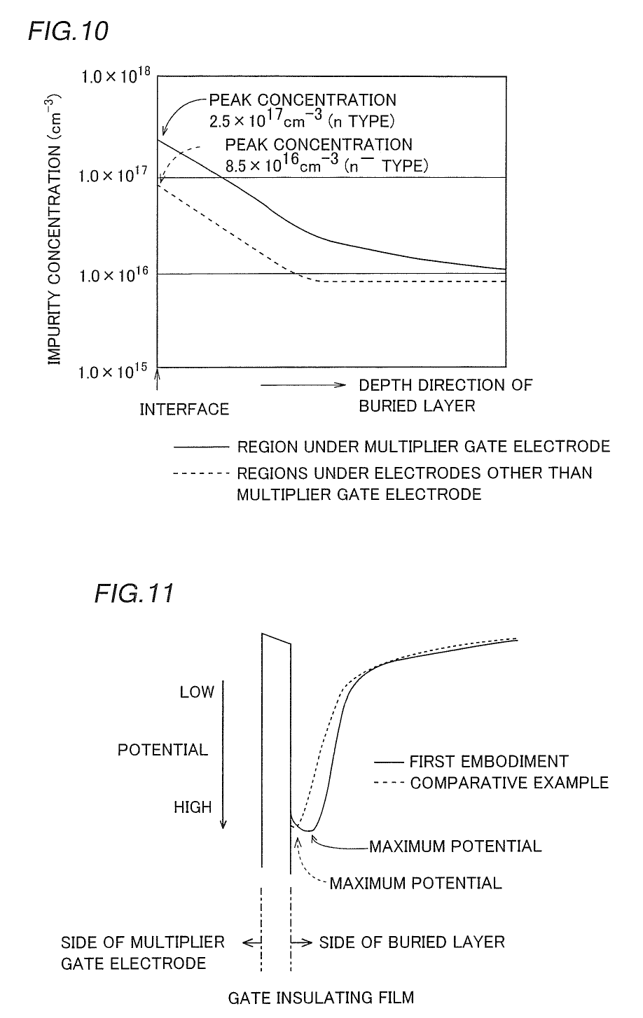

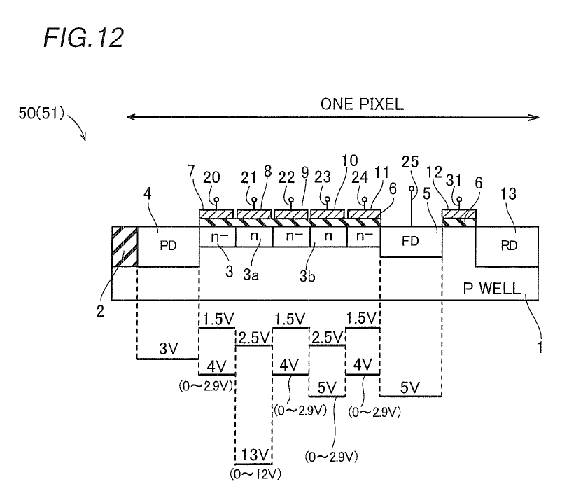

The potentials in the vicinity of the interface between the gate insulating film 6 and the buried layer 3 and the profiles of the impurities implanted into the buried layer 3 according to the first embodiment of the present invention will be described with reference to FIGS. 10 and 11.

As shown by a solid line of FIG. 10, an impurity concentration of the portion (electron multiplying portion 3a) (see FIG. 3) of the buried layer 3 located under the multiplier gate electrode 8 reaches a maximum on the interface between the gate insulating film 6 and the buried layer 3, and this concentration (peak concentration) is about 2.5×10¹⁷ cm⁻³. The impurity concentration is gradually reduced along a depth direction of the buried layer 3. As shown by a dotted line of FIG. 10, the impurity concentration of each of the portions of the buried layer 3 located under the remaining electrodes other than the multiplier gate electrode 8 reaches a maximum on the interface between the gate insulating film 6 and the buried layer 3, and this concentration (peak concentration) is about 8.5×10¹⁶ cm⁻³. The impurity concentration is gradually reduced along a depth direction of the buried layer 3.

Comparison of a case where the peak concentration of the impurity in the portion (electron multiplying portion 3a) of the buried layer 3 located under the multiplier gate electrode 8 is about 2.5×10¹⁷ cm⁻³ and a case where the peak concentration of the impurity in each of the portions of the buried layer 3 located under the remaining electrodes other than the multiplier gate electrode 8 is about 8.5×10¹⁶ cm⁻³ as a comparative example will be described. In the comparative example, the potential of the portion of the buried layer 3 located under the multiplier gate electrode 8 reaches a maximum in the vicinity of the interface between the gate insulating film 6 and the buried layer 3 as shown by the dotted line in FIG. 11. In the first embodiment where the peak concentration of the impurity in the portion (electron multiplying portion 3a) of the buried layer 3 located under the multiplier gate electrode 8 is about 2.5×10¹⁷ cm⁻³, on the other hand, a maximum point of the potential is deep with respect to the depth direction of the buried layer 3 as shown by the solid line of FIG. 11. In the other hand, the maximum point of the potential is separated from the interface between the gate insulating film 6 and the buried layer 3. Consequently, the channel of electrons is separated from the interface between the gate insulating film 6 and the buried layer 3.

It has been confirmed from a simulation conducted by the inventors that the channel of electrons is formed on the position separated from the interface between the multiplier gate electrode 8 and the buried layer 3 when a voltage of about 3 V is applied to the buried layer 3 having the peak concentration of the impurity of about 8.5×10¹⁶ cm⁻³ (comparative example), while the channel of the electrons is formed in the vicinity of the interface between the multiplier gate electrode 8 and the buried layer 3 and electrons are transferred and multiplied while rubbing the interface when a voltage of 12 V is applied to the buried layer 3. In a case where a voltage of about 12 V is applied to the buried layer 3 having the peak concentration of the impurity of about 2.5×10¹⁷ cm⁻³ (first embodiment), on the other hand, it has been confirmed that the channel of the electrons is formed separated from the interface between the multiplier gate electrode 8 and the buried layer 3.

From an experiment conducted by the inventors, it has been confirmed that a multiplication factor of electrons is improved by about three times as compared with a case where the peak concentration of the impurity is about 8.5×10¹⁶ cm⁻³ also when a voltage applied to the multiplier gate electrode 8 is reduced from a prescribed voltage by 2 V, in a case where the peak concentration (about 2.5×10¹⁷ cm⁻³) of the impurity in the portion of the buried layer 3 located under the multiplier gate electrode 8 (electron multiplying portion 3a) is larger than the peak concentration (about 8.5×10¹⁶ cm⁻³) of the impurity in the portion of the buried layer 3 located under each of the remaining electrodes other than the multiplier gate electrode 8. This is conceivably because the peak position (electron channel) of the potential of the portion of the buried layer 3 located under the multiplier gate electrode 8 is separated from the interface by increasing the peak concentration of the impurity on the portion of the buried layer 3 located under the multiplier gate electrode 8 even when a high voltage is applied to the multiplier gate electrode 8 in multiplying electrons, and hence electrons are effectively multiplied.

When the aforementioned impurity concentration of the buried layer 3 is uniformed, the electron channel on the portion located under the multiplier gate electrode 8, to which a high voltage is applied, is disadvantageously relatively shallower than the electron channel on the portion located under each of the remaining electrodes, to which a low electrode is applied, other than the multiplier gate electrode 8 with respect to the depth direction of the buried layer 3. On the other hand, according to the first embodiment, as hereinabove described, the peak concentration (about 2.5×10¹⁷ cm⁻³) of the impurity of a region of the buried layer 3 corresponding to the portion located under the multiplier gate electrode 8 is higher than the peak concentration (about 8.5×10¹⁶ cm⁻³) of the impurity of a region of the buried layer 3 corresponding to the portion located under each of the remaining electrodes other than the multiplier gate electrode 8, whereby the electron channel located under the multiplier gate electrode 8 is prevented from being shallower than the electron channel located under each of the remaining electrodes other than the multiplier gate electrode 8 with respect to the interface of the buried layer 3 and the electron channel can be rendered deeper from the surface of the substrate. Consequently, interaction between an interface state of the surface of the buried layer 3 and electrons can be suppressed and hence reduction of noise and the quantity of signals caused by this interaction can be suppressed. Thus, efficiency of multiplication of electrons can be increased. The peak concentration of the impurity of the region of the buried layer 3 corresponding to the portion located under the multiplier gate electrode 8 is higher than the peak concentration of the impurity of the region of the buried layer 3 corresponding to the portion located under each of the remaining electrodes other than the multiplier gate electrode 8, whereby a potential well formed under the multiplier gate electrode 8 can be kept deeper also when the voltage applied to the multiplier gate electrode 8 is slightly reduced, and hence power consumption of the CMOS image sensor can be reduced by reducing the voltage applied to the multiplier gate electrode 8. The peak concentration of the impurity of the region of the buried layer 3 corresponding to the portion located under the multiplier gate electrode 8 is higher than the peak concentration of the impurity of the region of the buried layer 3 corresponding to the portion located under the transfer gate electrode 7, whereby a potential barrier can be easily formed between the PD portion 4 and the electron multiplying portion 3a. The peak concentration of the impurity of the region of the buried layer 3 corresponding to the portion located under the multiplier gate electrode 8 is higher than the peak concentration of the impurity of the region of the buried layer 3 corresponding to the portion located under the transfer gate electrode 9, whereby a potential barrier can be easily formed between the electron multiplying portion 3a and the electron storage portion 3b, and difference in potentials between the portions of the buried layer 3 located under the multiplier gate electrode 8 and the transfer gate electrode 9 can be increased.

According to the first embodiment, as hereinabove described, a depth from the surface of the semiconductor substrate 100 (interface between the buried layer 3 and the gate insulating film 6) which is a position where the potential of the region (electron multiplying portion 3a) corresponding to the portion located under the multiplier gate electrode 8 reaches a maximum is larger than a depth from the surface of the semiconductor substrate 100 which is a position where the potential of the region corresponding to the portion located under each of the remaining electrodes other than the multiplier gate electrode 8 reaches a maximum, when the same voltages are applied to the multiplier gate electrode 8 and the remaining electrodes, whereby the electron channel can be easily rendered deeper from the surface of the semiconductor substrate 100.

According to the first embodiment, as hereinabove described, the CMOS image censor comprises the transfer gate electrode 7 provided on a side of multiplier gate electrode 8 opposite to the transfer gate electrode 9 and the read gate electrode 11 provided on a side of the storage gate electrode 10 opposite to the transfer gate electrode 9, whereby potential barriers can be formed between the PD portion 4 and the electron multiplying portion 3a and between the electron storage portion 3b and the FD region 5 by applying voltages of about 0 V to the transfer gate electrode 7 and the read gate electrode 11 when electrons are multiplied between the multiplier gate electrode 8 and the storage gate electrode 10. Thus, the electrons can be inhibited from leaking toward the PD portion 4 and the FD region 5 from the electron multiplying portion 3a and the electron storage portion 3b respectively.

According to the first embodiment, as hereinabove described, the impurity concentrations of the regions of the buried layer 3 corresponding to the portions located under the transfer gate electrodes 7 and 9, the storage gate electrode 10 and the read gate electrode 11 are rendered substantially equal to each other (n⁻-type), whereby the portions of the buried layer 3 (impurity region) located under the transfer gate electrodes 7 and 9, the storage gate electrode 10 and the read gate electrode 11 can be easily formed through the same step.

According to the first embodiment, as hereinabove described, the portions of the buried layer 3 located under the transfer gate electrode 7, the multiplier gate electrode 8, the transfer gate electrode 9, the storage gate electrode 10 and the read gate electrode 11 are formed by the n-type impurity region, whereby the electrons generated on the PD portion 4 can be transferred and multiplied on the buried layer 3.

### Second Embodiment

In a CMOS image sensor according to a second embodiment, a peak concentration of an impurity of a portion (electron storage portion 3b) of a buried layer 3 located under a storage gate electrode 10 is larger than a peak concentration of an impurity of each of portions of the buried layer 3 located under a transfer gate electrodes 7 and 9 and a read gate electrode 11, dissimilarly to the aforementioned first embodiment.

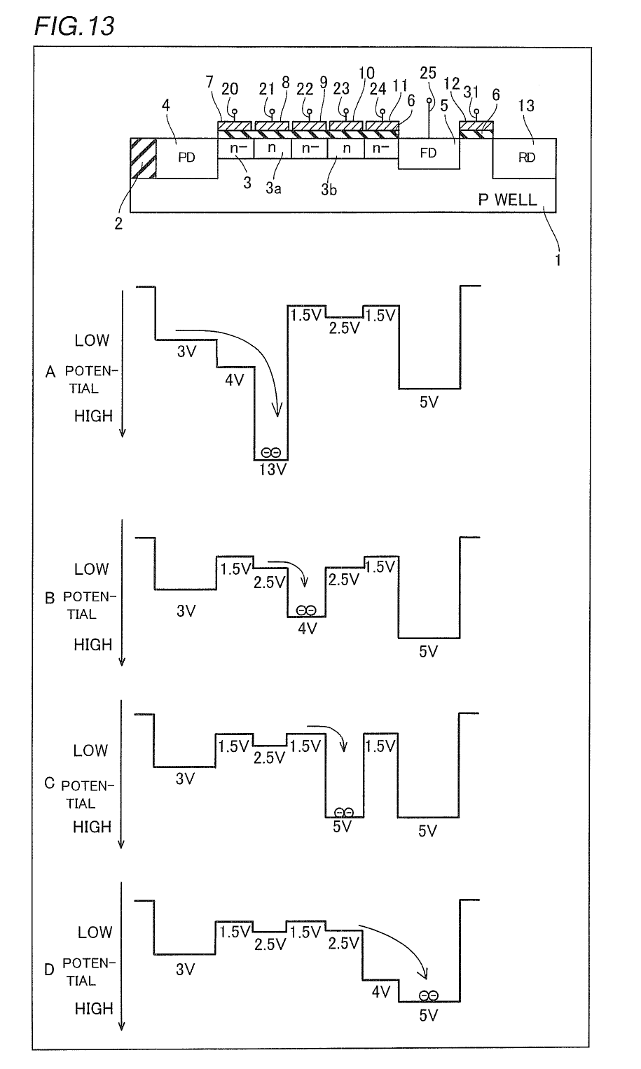

According to the second embodiment, the peak concentration of the impurity of the portion (electron storage portion 3b) of the buried layer 3 located under the storage gate electrode 10 is about 2.5×10¹⁷ cm⁻³ identical with the peak concentration of the impurity of an electron multiplying portion 3a, as shown in FIG. 12. In the other hand, the peak concentration of the impurity of each of the portions of the buried layer 3 located under the multiplier gate electrode 8 and the storage gate electrode 10 is larger than the peak concentration of the impurity of each of the portions of the buried layer 3 located under the transfer gate electrodes 7 and 9 and the read gate electrode 11. The remaining structure of the second embodiment is similar to that of the aforementioned first embodiment.

Electron transferring and multiplying operations of the CMOS image sensor according to the second embodiment will be now described with reference to FIGS. 6, 8, 13 and 14.

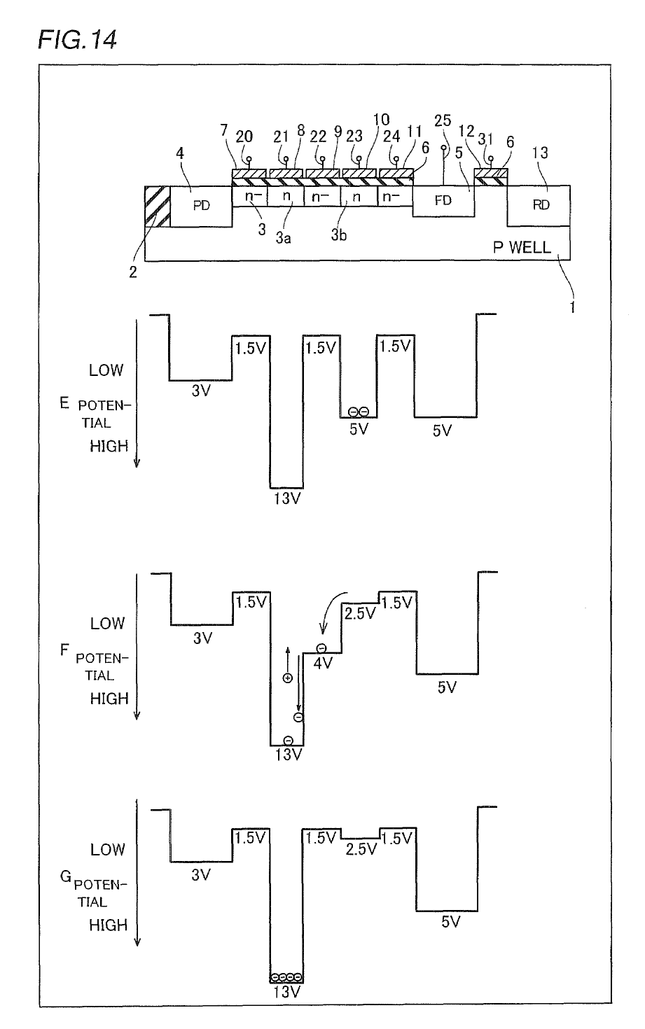

When light is incident upon a PD portion 4, electrons are generated in the PD portion 4 by photoelectric conversion. In a period A shown in FIGS. 6 and 13, a voltage of about 12 V is applied to the multiplier gate electrode 8 after a voltage of about 2.9 is applied to the transfer gate electrode 7. Thus, the potential of the portion of the buried layer 3 located under the multiplier gate electrode 8 is controlled to a high potential of about 13 V in the state where the potential of the portion of the buried layer 3 located under the transfer gate electrode 7 is controlled to a potential of about 4 V. At this time, electrons generated by the PD portion 4 (about 3 V) are transferred to the portion (electron multiplying portion 3a) of the buried layer 3 located under the multiplier gate electrode 8 (higher potential of about 13 V) through the portion of the buried layer 3 located under the transfer gate electrode 7 (about 4V), and the electrons are multiplied on the electron multiplying portion 3a by impact ionization. Thereafter a voltage of about 0 V is applied to the transfer gate electrode 7.

In a period B, a voltage of about 2.9 V is applied to the transfer gate electrode 9 and a voltage of about 0 V is thereafter applied to the multiplier gate electrode 8. Thus, electrons are transferred from the electron multiplying portion 3a (about 2.5 V) under the multiplier gate electrode 8 to the portion of the buried layer 3 located under the transfer gate electrode 9 (higher potential of about 4 V).

In a period C, a voltage of about 2.9 is applied to the storage gate electrode 10 and a voltage of about 0 V is thereafter applied to the transfer gate electrode 9. Thus, the electrons are transferred from the portion of the buried layer 3 located under the transfer gate electrode 9 to the portion (electron storage portion 3b) of the buried layer 3 located under the storage gate electrode 10 (higher potential of about 5 V).

In a period D, a voltage of about 2.9 V is applied to the read gate electrode 11, to control the potential of the portion of the buried layer 3 located under the read gate electrode 11 to a potential of about 4 V. Then a voltage of about 0 V is applied to the storage gate electrode 10. Thus, the electrons are transferred to an FD region 5 through the portion of the buried layer 3 located under the read gate electrode 11 (about 4 V). Thus, the electron transferring operation is completed.

In the electron multiplying operation, a voltage of about 12 V is applied to the multiplier gate electrode 8 in a period E shown in FIGS. 8 and 14 and a voltage of about 2.9 V is applied to the transfer gate electrode 9 in a period F, in the state where the portion (electron storage portion 3b) of the buried layer 3 located under the storage gate electrode 10 stores electrons by performing the operations of the periods A to C in FIGS. 6 and 13. Thus, the portion (electron multiplying portion 3a) of the buried layer 3 located under the multiplier gate electrode 8 is controlled to a potential of about 13 V and the portion of the buried layer 3 located under the transfer gate electrode 9 is thereafter controlled to a potential of about 4 V. Then a voltage of about 0 V is applied to the storage gate electrode 10, to transfer the electrons stored in the electron storage portion 3b to the portion (electron multiplying portion 3a) (higher potential of about 13 V) of the buried layer 3 located under the multiplier gate electrode 8 through the portion of the buried layer 3 located under the transfer gate electrode 9 (about 4 V).

The electrons are transferred to the electron multiplying portion 3a to be multiplied in the aforementioned manner. A voltage of about 0 V is applied to the transfer gate electrode 9 in a period G, thereby completing the electron multiplying operation.

According to the second embodiment, as hereinabove described, the peak concentration (about 2.5×10¹⁷ cm⁻³) of the impurity of a region of the buried layer 3 corresponding to the portion located under the storage gate electrode 10 is higher than the peak concentration (about 8.5×10¹⁶ cm⁻³) of the impurity of a region of the buried layer 3 corresponding to the portion located under the transfer gate electrode 9, whereby the potential of the region of the buried layer 3 corresponding to the portion located under the storage gate electrode 10 can be increased as compared with a case where the peak concentration of the impurity of the region of the buried layer 3 corresponding to the portion located under the storage gate electrode 10 is equal to the peak concentration of the impurity of the region of the buried layer 3 corresponding to the portion located under the transfer gate electrode 9, and hence a larger number of electrons can be held.

According to the second embodiment, as hereinabove described, the peak concentration of the impurity of the region of the buried layer 3 corresponding to the portion located under the storage gate electrode 10 and the peak concentration of the impurity of the region of the buried layer 3 corresponding to the portion located under the multiplier gate electrode 8 are substantially equal to each other, whereby the electron storage portion 3b under the storage gate electrode 10 and the electron multiplying portion 3a under the multiplier gate electrode 8 can be simultaneously formed.

According to the second embodiment, as hereinabove described, the impurity concentrations of the regions of the buried layer 3 corresponding to the portions located under the transfer gate electrodes 7 and 9 and the read gate electrode 11 are substantially equal to each other (n⁻-type), whereby the portions of the buried layer 3 (impurity region) located under the transfer gate electrodes 7 and 9 and the read gate electrode 11 can be easily formed through the same step.

The remaining effects of the second embodiment are similar to those of the aforementioned first embodiment.

Although the present invention has been described and illustrated in detail, it is clearly understood that the same is by way of illustration and example only and is not to be taken by way of limitation, the spirit and scope of the present invention being limited only by the terms of the appended claims.

For example, while each of the aforementioned first and second embodiments is applied to the active CMOS image sensor amplifying signal charges in each pixel 50 as an exemplary image sensor, the present invention is not restricted to this but is also applicable to a passive CMOS image sensor not amplifying signal charges in each pixel.

While the five electrodes, i.e., the transfer gate electrode 7, the multiplier gate electrode 8, the transfer gate electrode 9, the storage gate electrode 10 and the read gate electrode 11 are provided between the PD portion 4 and the FD region 5 in each of the aforementioned first and second embodiments, the present invention is not restricted to this but electrodes between the PD portion 4 and the FD region 5 may be formed by three or four electrodes.

While the buried layer 3, the PD portion 4 and the FD region 5 are formed on the surface of the p-type silicon region 1 formed on the surface of the n-type silicon substrate (not shown) in each of the aforementioned first and second embodiments, the present invention is not restricted to this but the buried layer 3, the PD portion 4 and the FD region 5 may be formed on the surface of the p-type silicon substrate.

While electrons are employed as the signal charges in each of the aforementioned first and second embodiments, the present invention is not restricted to this but holes may alternatively be employed as the signal charges by entirely reversing the conductivity type of the substrate impurity and the polarities of the applied voltages.

While As (arsenic) is implanted so that the portions of the buried layer 3 located under the multiplier gate electrode 8 and the storage gate electrode 10 have high concentrations in each of the aforementioned first and second embodiments, the present invention is not restricted to this but a dopant other than As (arsenic) may be implanted.

What is claimed is:

1. An image sensor comprising:
a charge storage portion for storing signal charges;
a first electrode for applying a voltage to said charge storage portion;
a charge increasing portion for increasing the signal charges stored in said charge storage portion by impact-ionization;
a second electrode for applying a voltage to said charge increasing portion;
a third electrode for transferring the signal charges, provided between said first electrode and said second electrode; and
an impurity region of a first conductive type for forming a path through which the signal charges are transferred, provided on portions located under at least said first electrode, said second electrode and said third electrode, wherein
an impurity concentration of a region of said impurity region corresponding to the portion located under said second electrode is higher than an impurity concentration of a region of said impurity region corresponding to the portion located under said third electrode.

2. The image sensor according to claim 1, further comprising a semiconductor substrate, wherein
said impurity region is provided on said semiconductor substrate, and
a depth from a surface of said semiconductor substrate, which is a position where a potential of the portion located under said second electrode reaches a maximum, is larger than a depth which is a position where a potential of the portion located under said third electrode reaches a maximum when applying the same voltage.

3. The image sensor according to claim 1, wherein
the impurity concentrations of the regions of said impurity region of said first conductive type corresponding to the portions located under said first electrode and said third electrode are substantially equal to each other, and the impurity concentration of the region of said impurity region corresponding to the portion located under said second electrode is higher than the impurity concentration of each of the regions of said impurity region corresponding to the portions located under said first electrode and said third electrode.

4. The image sensor according to claim 3, wherein
a potential of the region of said impurity region corresponding to the portion located under said second electrode in applying an OFF-state voltage to said second electrode is larger than a potential of each of the regions of said impurity region corresponding to the portions located under said first electrode and said third electrode in applying OFF-state voltages to said first electrode and said third electrode.

5. The image sensor according to claim 3, further comprising a semiconductor substrate, wherein
said impurity region is provided on said semiconductor substrate,
depths from a surface of said semiconductor substrate, which are positions where potentials of the portions located under said first electrode and said third electrode reach maximums, are substantially equal to each other when applying the same voltage, and a depth from the surface of said semiconductor substrate, which is a position where a potential of the portion located under said second electrode reaches a maximum is larger than each of the depths from the surface of said semiconductor substrate, which are the positions where the potentials of the portions located under said first electrode and said third electrode reach maximums when applying the same voltage.

6. The image sensor according to claim 1, wherein
an impurity concentration of a region of said impurity region corresponding to the portion located under said first electrode is higher than the impurity concentration of the region of said impurity region corresponding to the portion located under said third electrode.

7. The image sensor according to claim 6, wherein
the impurity concentrations of the regions of said impurity region corresponding to the portions located under said first electrode and said second electrode are substantially equal to each other, and the impurity concentration of each of the regions of said impurity region corresponding to the portions located under said first electrode and said second electrode is higher than the impurity concentration of the region of said impurity region corresponding to the portion located under said third electrode.

8. The image sensor according to claim 7, wherein
a potential of each of the regions of said impurity region corresponding to the portions located under said first electrode and said second electrode in applying OFF-state voltages to said first electrode and said second electrode is larger than a potential of the region of said impurity region corresponding to the portion located under said third electrode in applying an OFF-state voltage to said third electrode.

9. The image sensor according to claim 7, further comprising a semiconductor substrate, wherein
said impurity region is provided on said semiconductor substrate,
depths from a surface of said semiconductor substrate, which are positions where potentials of the portions located under said first electrode and said second electrode reach maximums, are substantially equal to each other when applying the same voltage, and each of the depths from the surface of said semiconductor substrate, which are the positions where the potentials of the portions located under said first electrode and said second electrode reach maximums when applying the same voltage is larger than a depth from the surface of said semiconductor substrate, which is a position where a potential of the portion located under said third electrode reaches a maximum.

10. The image sensor according to claim 1, further comprising:
a fourth electrode provided on a side of said second electrode opposite to said third electrode; and
a fifth electrode provided on a side of said first electrode opposite to said third electrode, wherein
said impurity region is provided also on portions located under said fourth electrode and said fifth electrode, and the impurity concentration of the region of said impurity region corresponding to the portion located under said second electrode is higher than the impurity concentration of a region of said impurity region corresponding to each of the portions located under said fourth electrode and said fifth electrode.

11. The image sensor according to claim 10, wherein
the impurity concentrations of the regions of said impurity region corresponding to the portions located under said first electrode, said third electrode, said fourth electrode and said fifth electrode are substantially equal to each other, and the impurity concentration of the region of said impurity region corresponding to the portion located under said second electrode is higher than the impurity concentration of each of the regions of said impurity region corresponding to the portions located under said first electrode, said third electrode, said fourth electrode and said fifth electrode.

12. The image sensor according to claim 10, wherein
the impurity concentrations of the regions of said impurity region corresponding to the portions located under said third electrode, said fourth electrode and said fifth electrode are substantially equal to each other, and the impurity concentration of each of the regions of said impurity region corresponding to the portions located under said first electrode and said second electrode is higher than the impurity concentration of each of the regions of said impurity region corresponding to the portions located under said third electrode, said fourth electrode and said fifth electrode.

13. The image sensor according to claim 10, further comprising:
a photoelectric conversion portion provided on a side of said fourth electrode opposite to said second electrode; and
a voltage conversion portion provided on a side of said fifth electrode opposite to said first electrode.

14. The image sensor according to claim 1, wherein
said impurity region of said first conductive type on the regions of said impurity region corresponding to the portions located under said first electrode, said second electrode and said third electrode has an n-type.

15. A CMOS image sensor comprising:
a charge storage portion for storing signal charges;
a first electrode for applying a voltage to said charge storage portion;
a charge increasing portion for increasing the signal charges stored in said charge storage portion by impact-ionization;
a second electrode for applying a voltage to said charge increasing portion;
a third electrode for transferring the signal charges, provided between said first electrode and said second electrode; and
an impurity region of a first conductive type for forming a path through which the signal charges are transferred, provided on portions located under at least said first electrode, said second electrode and said third electrode, wherein
said charge storage portion, said charge increasing portion, said first electrode, said second electrode and said third electrode are provided in one pixel, and
an impurity concentration of a region of said impurity region corresponding to the portion located under said second electrode is higher than an impurity concentration of a region of said impurity region corresponding to the portion located under said third electrode.

16. The CMOS image sensor according to claim 15 further comprising a semiconductor substrate, wherein
said impurity region is provided on said semiconductor substrate, and
a depth from a surface of said semiconductor substrate, which is a position where a potential of the portion located under said second electrode reaches a maximum, is larger than a depth which is a position where a potential of the portion located under said third electrode reaches a maximum when applying the same voltage.

17. The CMOS image sensor according to claim 15, wherein
an impurity concentration of a region of said impurity region corresponding to the portion located under said first electrode is higher than the impurity concentration of the region of said impurity region corresponding to the portion located under said third electrode.

18. The CMOS image sensor according to claim 15, further comprising:
a fourth electrode provided on a side of said second electrode opposite to said third electrode; and
a fifth electrode provided on a side of said first electrode opposite to said third electrode, wherein
said impurity region is provided also on portions located under said fourth electrode and said fifth electrode, and the impurity concentration of the region of said impurity region corresponding to the portion located under said second electrode is higher than the impurity concentration of a region of said impurity region corresponding to each of the portions located under said fourth electrode and said fifth electrode.

19. The CMOS image sensor according to claim 18, further comprising:
a photoelectric conversion portion provided on a side of said fourth electrode opposite to said second electrode; and
a voltage conversion portion provided on a side of said fifth electrode opposite to said first electrode.

20. The CMOS image sensor according to claim 15, wherein
said impurity region of said first conductive type on the regions of said impurity region corresponding to the portions located under said first electrode, said second electrode and said third electrode has an n-type.
